(19) United States
(12) Patent Application Publication
(10) Pub. No.: US 2010/0079094 A1
(43) Pub. Date: Apr. 1, 2010

(54) Enclosure acoustic compensation

(76) Inventors: Willem M. Beltman, West Linn, OR (US); Rafael De la Guardia, Guadalajara (MX); Jose Cordova, Zapopan (MX); Jessica Gulbrand, Forest Grove, OR (US)

Correspondence Address: INTEL CORPORATION;c/o CPA Global, P.O. BOX 52050, MINNEAPOLIS, MN, 55402, US

(21) Appl. No.: 12/286,498

(22) Filed: Sep. 30, 2008

(51) Int. Cl. H02P 3/00; H05K 7/20

(52) U.S. Cl. 318/460; 361/679.48

(57) ABSTRACT

In some embodiments, an amplification spectrum for an electronic device enclosure is identified and/or determined to improve a user's audio environment, e.g., by reducing unwanted noise such as fan noise and/or by processing audio signals that have been or will be distorted by the enclosure acoustics.

### TECHNICAL FIELD

The present invention relates generally to adjusting devices and/or audio signals based on an acoustic amplification spectrum for an electronic device.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1A is a graph showing a noise emission spectrum for an exemplary fan acoustic noise spectrum.

FIG. 1B is a graph showing an acoustic amplification spectrum for an exemplary computer enclosure.

FIG. 1C is a graph showing an acoustic amplification spectrum for an exemplary computer notebook enclosure.

FIG. 2 is a block diagram of a computer platform with acoustic adjustment in accordance with some embodiments.

FIG. 3 is a block diagram of a fan speed controller in accordance with some embodiments.

FIG. 4 is a block diagram of a fan speed controller with an enclosure spectrum detector in accordance with some embodiments.

FIG. 5 is a block diagram of a fan speed controller with an enclosure spectrum detector in accordance with some additional embodiments.

FIG. 6 is a block diagram an acoustic balance module in accordance with some embodiments.

### DETAILED DESCRIPTION

Noise sources, for example fans, are usually noisier when they are installed in systems because of coupling with the acoustic cavity modes of the enclosure. Enclosures can also distort audio input and output signals, e.g., audio input into microphones and output from speakers in handheld and notebook devices. In fact, the amplification due to enclosure acoustics may be as large as 15 dB, a factor of 30. Accordingly, solutions for addressing these issues are desired.

By identifying and/or determining an amplification spectrum for an electronic device enclosure, it is possible to improve a user's audio environment, e.g., reducing unwanted noise and/or processing audio that has been or will be distorted by the enclosure acoustics. For example, fan noise may be reduced by avoiding operations where fan audio emission peaks concur with enclosure amplification peaks. In some cases, it may even be possible to run the fan faster and get enhanced thermal performance and lower overall noise levels, which may be counter-intuitive. In some embodiments, enclosure acoustic spectrums may also be used to mitigate against distortion effects, e.g., for audio input and output.

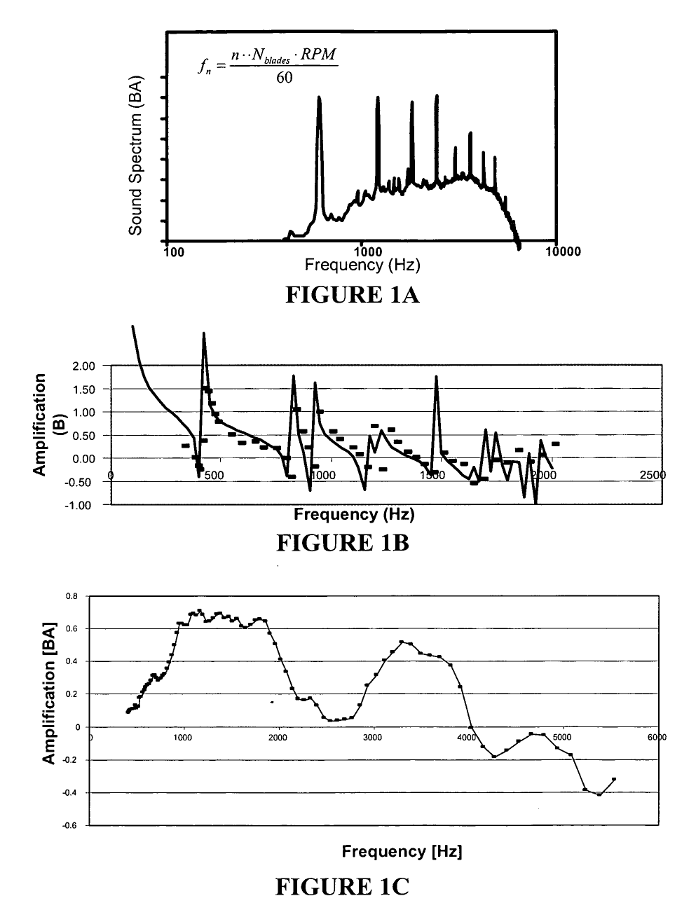

FIG. 1A shows a typical noise emission spectrum for an axial fan running at a particular frequency. The figure shows the A-weighted sound power level in Bels [BA] as a function of sound frequency. FIG. 1A shows that the spectrum is made up of broadband components and distinct peaks at the blade-pass-frequency and its higher harmonics. The frequencies of these peaks can easily be calculated from the fan speed according to the formula indicated in the figure. In this formula, “n” is an integer, “Nblades” is the number of blades and “RPM” is the rotational fan speed. Thus, in this example, with the first peak at about 600 Hz., the fan would be running at about 5100 RPM, assuming a fan with seven blades.

As mentioned above, the noise emission of the fan is altered when it is installed inside an enclosure because of coupling with acoustic cavity modes of the enclosure. FIGS. 1B and 1C show exemplary amplification spectrums for two different computer enclosures, the latter being for a notebook computer. For the spectrum of FIG. 1B, the data was obtained through experimentation (curve formed from symbols) and simulations (curve with solid line). For the spectrum of FIG. 1C, the data was obtained through experimentation. Elementary noise sources, monopoles and dipoles, were used for this purpose. (It should be noted that most fans have a dipole noise emission characteristic.) The noise emission of these sources was determined as a function of frequency in a free field. Then, the sources were installed in a system enclosure and the acoustic sound power was measured again. The obtained amplification spectrum is shown in FIG. 1B. The scale here is in Bels [B] for sound power. An amplification of 1.5 B therefore corresponds to 15 dB, which is a factor of 30.

The results show a dramatic effect of the system enclosure. Amplifications of up to 1.5 B (15 dB=30x) were measured. Thus, it can be seen that if a peak in the noise emission spectrum corresponds to an amplification peak, excessive acoustic noise can result.

Thus, it can now be appreciated that the fan can be controlled such that peaks in its emission spectrum coincide with the valley in the amplification. For example, in FIG. 1C it would be beneficial to run the fan faster to shift an emission peak into the amplification valley (between 2000 and 3000 Hz.), resulting in a lower overall noise level.

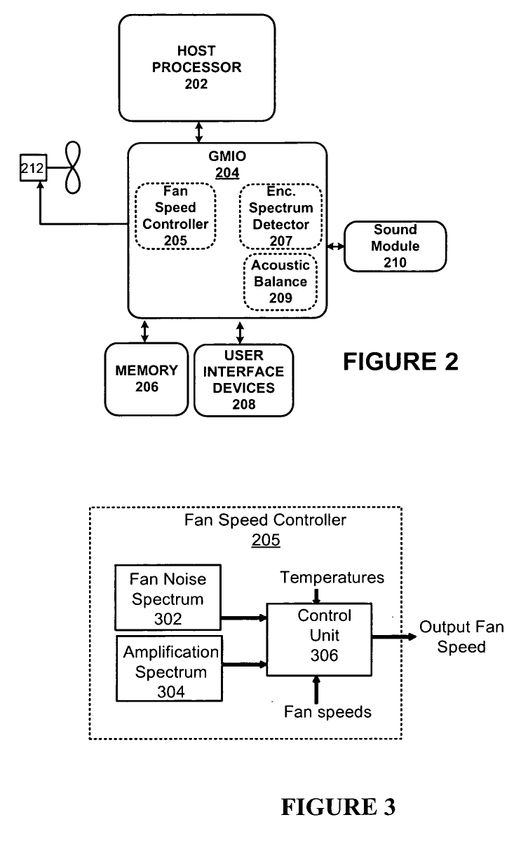

With reference to FIG. 2, one example of a portion of a computing platform is shown. The computing platform may implement a variety of different computing devices or other appliances with computing capability. Such devices include but are not limited to laptop computers, notebook computers, personal digital assistant devices (PDAs), cellular phones, audio and/or video media players, desktop computer, servers, and the like. The represented portion comprises one or more processors 202, graphics/memory/input/output (GMIO) control 204, memory 206, user interface devices 208, sound module 210, and fan 212. The processor(s) 202 is coupled to the memory 206, user interface devices 208, and sound module 210 through the GMIO control 204. The GMIO control 204 may comprise one or more blocks (e.g., chips or units within an integrated circuit) to perform various interface control functions (e.g., memory control, graphics control, I/O interface control, and the like). These circuits may be implemented on one or more separate chips and/or may be partially or wholly implemented within the processor(s) 502.

As shown, the GMIO 204 may also comprise one or more system functionality blocks including but not limited to a fan speed controller 205, and enclosure spectrum detector 207, and/or and acoustic balance block 209. (Any or all of these blocks could be implemented in other parts of the system such as in separate chips, in a processor 502, or elsewhere.) The fan speed controller controls the fan 212 based on various factors such as temperature, system environment management input and particular to the present disclosure, a noise emission spectrum for the fan 212, as well perhaps, as an enclosure spectrum for the enclosure housing the computer platform.

The enclosure spectrum detector 207 determines an amplification spectrum for the platform's enclosure. Some platforms may or may not include an enclosure spectrum detector, for example, they may be programmed with an amplification spectrum for their enclosure. However, a spectrum detector may be useful for determining a spectrum throughout the life of the platform, which may physically change or whose acoustic characteristics may otherwise change over time. The acoustic balance module 209 functions to balance audio signals input to the sound module 210 or generated from it based on an enclosure spectrum for the platform.

The memory 206 comprises one or more memory blocks to provide additional random access memory to the processor(s) 202. It may be implemented with any suitable memory including but not limited to dynamic random access memory, static random access memory, flash memory, or the like.

The user interface devices 510 comprise one or more devices such as a display, keypad, mouse, etc. to allow a user to interact with and perceive information from the computing platform. The sound module 210 may be implemented with any suitable sound processing, amplifying, and /or distributing circuitry to provide audio to one or more users and/or to receive audio information from outside of the platform. It may be integrated into one or more platform chips or it could be part of a separate chip or card.

FIG. 3 shows a fan speed controller 205 in accordance with some embodiments. It has memory with fan noise spectrum 302 and enclosure amplification spectrum 304. It also has a control unit 306 to process this information, along with system fan speed information (e.g., temperature and fan speed commands, e.g., from a system management module or from the platform operating system) to determine an output fan speed control to be applied to the fan 212. The control unit 306 operates to control the overall output fan speed based on the component temperatures and the system fan speed information, adjusted based on the fan noise spectrum 302 and enclosure amplification spectrum 304. For example, it may make an initial assessment, based on system information such as temperature and/or fan speed command(s), that the fan is to rotate at 5100 RPM, and then determine that this is concurrent with a fan noise peak and/or an enclosure amplification peak, and in response, adjust the fan speed upward to avoid either or both of these peaks. In most cases, depending on platform specifications, it would tend not to adjust output speed downward in limiting noise because it should still operate at a rate sufficient to adequately cool the platform. It may perform a cost/benefit analysis (e.g., via formula or look-up table) to weigh the benefits of reduced sound against the costs (e.g., increased power consumption) of higher fan speed, which may consume excess power. It may be seen that any suitable routine may be applied to control the resultant output fan speed, taking into account fan noise and/or enclosure amplification spectrum information to reduce fan noise and at the same time, maintain needed cooling from the fan.

It should be appreciated that the enclosure amplification spectrum may or may not be included for adjusting fan speed and reducing fan noise in some embodiments. That is, beneficial noise reduction may be attained using just the fan noise spectrum. However, in many cases, greater noise reduction will be achieved by considering enclosure amplification, as well as fan noise, spectrum information.

Enclosure amplification information may be provided in different ways. For example, it could be programmed into the platform, e.g., during manufacture or during operation, e.g., through a data port such as a USB port. Alternatively, it could be determined, e.g., automatically, in an enclosure spectrum detector 207.

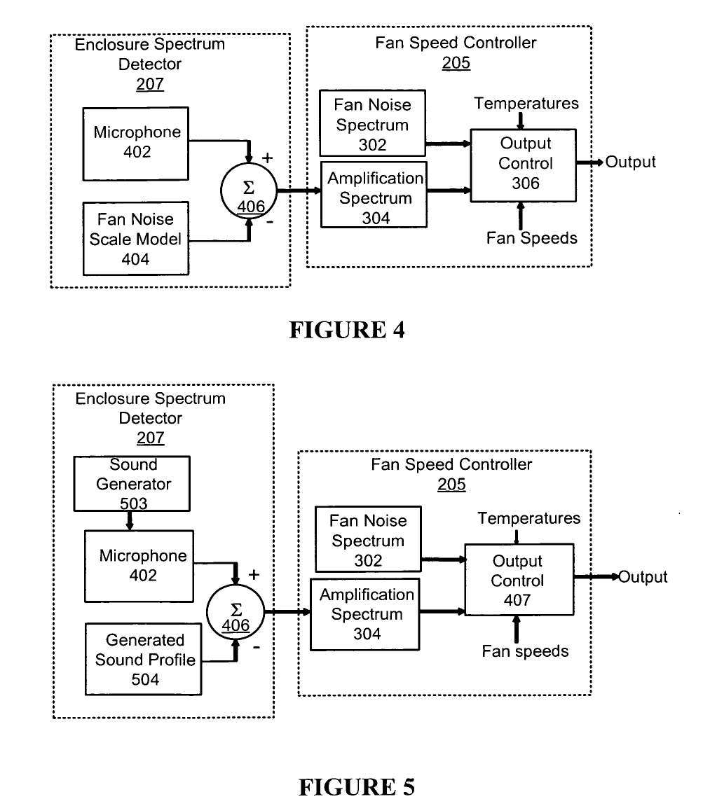

FIG. 4 shows a fan controller and enclosure spectrum detector in accordance with some embodiments. The spectrum detector 207 uses a microphone 402 (which may or may not be part of the detector), a fan noise scale model 404 and a summing (or difference as is the case here) block 406 to adaptively generate an amplification spectrum 304 as a function of rotational fan speed. The spectrum of the fan noise emission scales with speed according to fan laws. The noise of the fan in the system can be sensed with a low cost existing microphone 402, and then a discrete Fourier transform (DFT) such as a fast Fourier transform (FFT) may be performed. The peaks in the FFT spectrum are identified, and it is verified that the fan peak levels behave according to the fan scaling law. Enclosure amplifications will result in higher levels that can then be identified.

With reference to FIG. 5, a second method for performing automatic enclosure sensing is illustrated. With this embodiment, the enclosure spectrum detector 207 doesn't use the fan, itself, as a known, characterized noise source but rather uses a sound generator 503 with a known sound profile 504, such as a sine sweep signal. This signal produced by the sound generator may be at a low level in the platform environment, so as not to cause actual user annoyance, because the amplification is linear in nature. The sound signal may, for example, be a frequency sweep at a constant voltage for the source, resulting in a known sound output. The resulting sound level in the enclosure is sensed with a microphone 402, and the amplification spectrum 304 is extracted.

Enclosure detection, as disclosed herein, does not have to run continuously, but rather, can be run when the system is assembled, or periodic checks could be performed in case of changing system characteristics.

As taught above with reference to the fan speed controller 205, the amplification spectrum may then be used to avoid the fan blade-pass-frequency peaks from coinciding with amplification peaks.

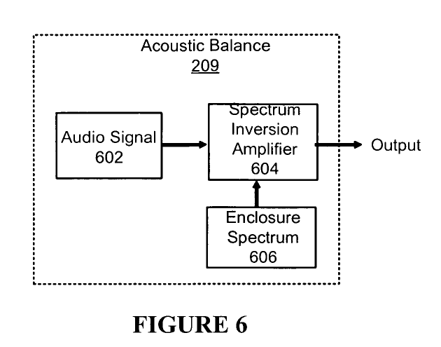

FIG. 6 shows an acoustic balance block in accordance with some embodiments. It comprises a spectrum inversion amplifier 604 with the enclosure amplification spectrum information 304 to control its amplification levels over the operating spectrum to essentially invert the amplification spectrum profile and amplify an incoming audio signal in accordance therewith. Thus, it serves to balance out the non-constant amplification effects of the enclosure to generate an output version of the audio signal that when applied as input to the system or as output, e.g., through a speaker, will be more balanced across the operating spectrum. Of course, this signal may be further processed, depending on particular applications and desired effects.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a fan speed controller to control rotational speed of a fan in an electronic device to reduce fan noise for a user.

2. The chip of claim 1, in which the electronic device is a notebook computer.

3. The chip of claim 1, in which the controller controls fan speed to avoid enclosure amplification peaks for the electronic device.

4. The chip of claim 3, in which the controller controls the fan speed to shift fan noise peaks into one or more valleys of an enclosure amplification spectrum.

5. The chip of claim 3, in which the controller controls the fan speed based on system inputs to promote sufficient cooling.

6. The chip of claim 5, in which the controller adjusts a fan speed command from the system to shift fan noise peaks away from enclosure amplification peaks.

7. The chip of claim 1, in which the controller is part of a computer platform interface control module.

8. The chip of claim 1, further comprising an enclosure spectrum detector to generate an enclosure amplification spectrum.

9. The chip of claim 8, in which the controller controls fan speed to avoid enclosure amplification peaks for the electronic device.

10. The chip of claim 9, in which the controller controls the fan speed to shift fan noise peaks into one or more valleys of the enclosure amplification spectrum.

11. A method, comprising:
controlling a fan based on its noise spectrum and an enclosure amplification spectrum of an electronic device to reduce generated fan noise.

12. The method of claim 11, in which controlling comprises identifying an initial fan speed based on system fan speed control commands and then adjusting it to move a fan noise peak away from a peak of the enclosure amplification spectrum.

13. The method of claim 12, in which the initial fan speed is increased to reduce fan noise.

14. The method of claim 12, comprising generating the enclosure amplification spectrum using a microphone and a known noise spectrum for the fan.

15. The method of claim 13, comprising generating the enclosure amplification spectrum using a sound generator and one or more microphones to measure enclosure acoustic amplification characteristics.

16. A computer system, comprising:
a processor;
a fan controller; and
a fan, wherein the processor, fan controller, and fan are to be housed in an enclosure, the fan speed controller to control rotational speed of the fan to reduce fan noise for a user.

17. The system of claim 16, in which the controller is part of a chip separate from the processor.

18. The system of claim 16, in which the controller controls fan speed to avoid enclosure amplification peaks for the enclosure.

19. The system of claim 18, in which the controller controls the fan speed to shift fan noise peaks into one or more valleys of the enclosure amplification spectrum.

20. The system of claim 19, in which the controller controls the fan speed based on system inputs to promote sufficient cooling.

21. A chip comprising:
a spectrum inversion amplifier with an enclosure amplification spectrum to control amplification levels of the spectrum inversion amplifier to inversely amplify an incoming audio signal in accordance with the enclosure amplification spectrum.

22. The chip of claim 21, comprising an enclosure amplification detector to generate the enclosure amplification spectrum.
